(19) United States
(12) Patent Application Publication
(10) Pub. No.: US 2017/0016112 A1
(43) Pub. Date: Jan. 19, 2017

(54) APPARATUS FOR PROCESSING SUBSTRATE AND METHOD OF MANUFACTURING ARTICLE

(71) Applicant: CANON KABUSHIKI KAISHA, Tokyo (JP)

(72) Inventor: Ryo Tanaka, Sakura-shi (JP)

(21) Appl. No.: 15/205,690

(22) Filed: Jul. 8, 2016

(30) Foreign Application Priority Data
Jul. 14, 2015 (JP) 2015-140785

(51) Int. Cl. C23C 16/44; H01L 21/306; H01L 21/67; C23C 16/52

(52) U.S. Cl. CPC C23C 16/44; C23C 16/52; H01L 21/306; H01L 21/67063

(57) ABSTRACT

An apparatus includes first and second processors to process a substrate, an adjuster to adjust a position of the substrate, a conveyance mechanism to convey the substrate, and a controller. The controller controls the adjuster to adjust a position of the substrate which is to be conveyed to the first processor, controls the conveyance mechanism to convey the substrate to the second processor without causing the adjuster to readjust the position of the substrate when there is a trouble in the first processor while the position of the substrate has been adjusted by the adjuster, and controls at least one of the conveyance mechanism and the second processor such that the substrate is arranged at a target position in the second processor.

### BACKGROUND OF THE INVENTION

Field of the Invention

The present invention relates to an apparatus for processing a substrate, which includes a plurality of processors which process a substrate, and a method of manufacturing an article, which manufactures an article by using the apparatus for processing a substrate.

Description of the Related Art

As an apparatus for processing a substrate, there is available, for example, a lithography apparatus (imprint apparatus, exposure apparatus, charge-particle beam drawing apparatus, or the like), a film formation apparatus (CVD apparatus or the like), a machining apparatus (laser machining apparatus or the like), or an inspection apparatus (overlay inspection apparatus or the like). In such an apparatus for processing a substrate, a substrate should be transferred to a target position in a substrate holder which holds a substrate. Japanese Patent Laid-Open Nos. 7-193112 and 2000-127069 disclose a technique associated with teaching for conveying a substrate to a target position at a conveyance destination.

Japanese Patent Laid-Open No. 2002-252263 discloses a processing system which picks up a wafer from a cassette, conveys the wafer to a processing apparatus through an orienter, and causes the processing apparatus to process the wafer. In this processing system, when a trouble is detected in a processing apparatus at the conveyance destination of a wafer, the wafer is returned to a standby port and then conveyed to another processing apparatus through the orienter.

In the scheme of conveying a wafer to another processing apparatus through the orienter again upon detection of a trouble in the processing apparatus at the conveyance destination of the wafer as disclosed in Japanese Patent Laid-Open No. 2002-252263, it takes much time to process the wafer by using the other processing apparatus.

### SUMMARY OF THE INVENTION

The present invention provides a technique advantageous in improving throughput when a given processor cannot process a substrate, and another processor processes it.

One of aspects of the present invention provides an apparatus for processing a substrate, comprising a plurality of processors configured to process a substrate, an adjuster configured to adjust a position of the substrate, a conveyance mechanism configured to convey the substrate, and a controller, wherein the controller controls the adjuster to adjust a position of a substrate to be processed which is to be conveyed to a first processor of the plurality of processors, the controller controls the conveyance mechanism to convey the substrate to be processed to a second processor of the plurality of processors without causing the adjuster to readjust the position of the substrate to be processed when there is a trouble in the first processor while the position of the substrate to be processed has been adjusted by the adjuster, and the controller controls at least one of the conveyance mechanism and the second processor such that the substrate to be processed is arranged at a target position in the second processor.

Further features of the present invention will become apparent from the following description of exemplary embodiments with reference to the attached drawings.

### BRIEF DESCRIPTION OF THE DRAWINGS

FIG. 1 is a view showing the schematic arrangement of an apparatus for processing a substrate according to one embodiment of the present invention;

FIG. 2 is a flowchart for explaining the operation of the apparatus for processing a substrate in a first mode;

FIG. 3 is a view schematically showing a table for selecting a processor;

FIG. 4 is a view schematically showing offset values set in the respective processors; and

FIG. 5 is a flowchart for explaining the operation of the apparatus for processing a substrate in a second mode.

### DESCRIPTION OF THE EMBODIMENTS

The present invention will be described below through an exemplary embodiment with reference to the accompanying drawings.

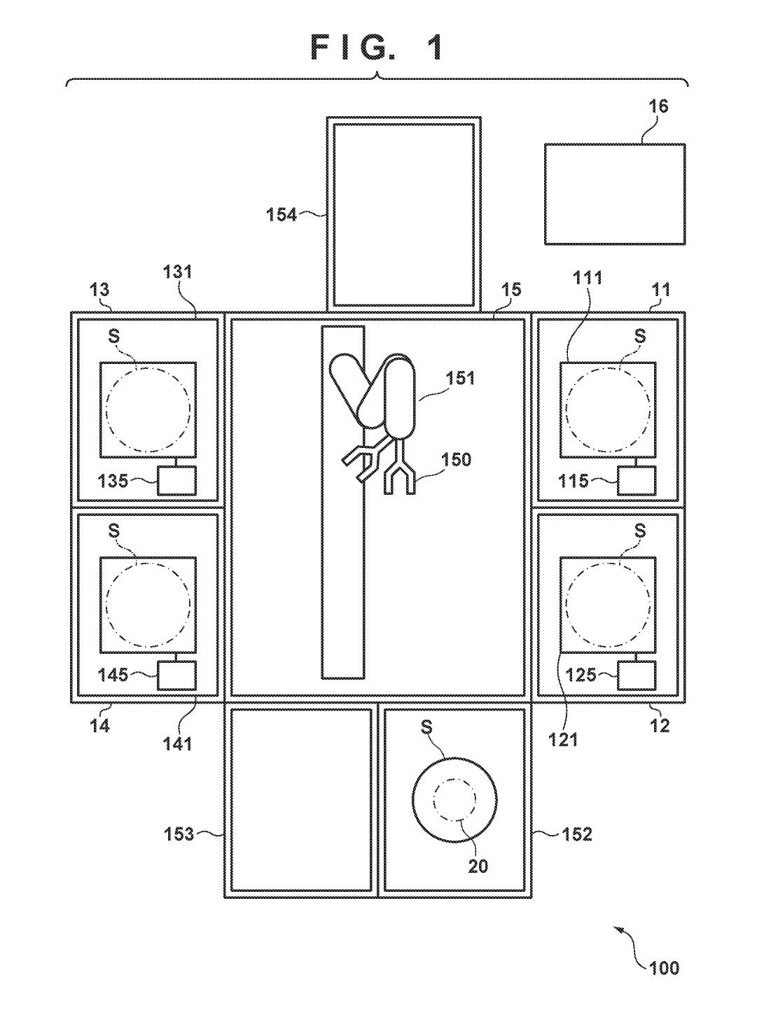

FIG. 1 shows the schematic arrangement of an apparatus 100 for processing a substrate according to one embodiment of the present invention. The apparatus 100 can include a plurality of processors 11, 12, 13, and 14 which process a substrate S, an adjuster 20 which adjusts at least the position of the position and rotation angle of the substrate S, a conveyance mechanism 15 which conveys the substrate S, and a controller 16. The apparatus 100 can further include a loading unit 152 for loading the substrate S into the apparatus 100 and an unloading unit 153 which unloads the substrate S from the apparatus 100. The apparatus 100 can also include a standby port 154.

Each of the plurality of processors 11, 12, 13, and 14 can be one of the following, for example: a lithography apparatus (imprint apparatus, exposure apparatus, charge-particle beam drawing apparatus, or the like), a film formation apparatus (CVD apparatus or the like), a machining apparatus (laser machining apparatus or the like), or an inspection apparatus (overlay inspection apparatus or the like). The imprint apparatus forms a pattern on a substrate by curing an imprint material such as a resin supplied onto the substrate while the resin is in contact with a mold (original). The exposure apparatus forms a latent image corresponding to the pattern of the original on a photoresist supplied onto the substrate by exposing the photoresist through the original. The charge-particle beam drawing apparatus forms a latent image on a photoresist supplied onto the substrate by drawing a pattern on the photoresist with a charge-particle beam.

The following will exemplify each of the processors 11, 12, 13, and 14 as an imprint apparatus which is one of lithography apparatuses. Note however that each of the processors 11, 12, 13, and 14 may be configured as another type of lithography apparatus or another type apparatus such as a film formation apparatus, machining apparatus, or inspection apparatus.

The processor 11 can include a substrate holder 111 which holds the substrate S and a driver 115 which drives the substrate holder 111 so as to adjust at least the position of the position and rotation angle of the substrate holder 111. The processor 12 can include a substrate holder 121 which holds the substrate S and a driver 125 which drives the substrate holder 121 so as to adjust at least the position of the position and rotation angle of the substrate holder 121. The processor 13 can include a substrate holder 131 which holds the substrate S and a driver 135 which drives the substrate holder 131 so as to adjust at least the position of the position and rotation angle of the substrate holder 131. The processor 14 can include a substrate holder 141 which holds the substrate S and a driver 145 which drives the substrate holder 141 so as to adjust at least the position of the position and rotation angle of the substrate holder 141.

The conveyance mechanism 15 can include a conveyance robot 151 which holds and conveys the substrate S with a hand 150. The conveyance robot 151 can be a horizontal multijoint type robot (scalar robot).

An adjuster 20 is configured to adjust at least the position of the position and rotation angle of the substrate S, and is preferably configured to adjust both the position and rotation angle of the substrate S. The adjuster 20 can be configured as a pre-alignment apparatus. For example, the adjuster 20 includes a measurement unit and a driver. The measurement unit measures the position and rotation angle of the substrate S. The driver drives the substrate S so as to adjust the position and rotation angle of the substrate S. The measurement unit can perform measurement by detecting the positions of the entire edge of the substrate S. With regard to the adjustment of the substrate S by the adjuster 20, the apparatus 100 can include a plurality of modes including the first and second modes. The apparatus 100 can select one of the plurality of modes in accordance with a command which can be provided via an input device (not shown).

In the first mode, the measurement unit of the adjuster 20 can measure a positional shift amount (Δx, Δy) relative to a target position (x, y) of the substrate S and a rotational shift amount (Δθ) relative to a target rotation angle (θ) of the substrate S. The driver drives the substrate S so as to make the positional shift amount (Δx, Δy) and the rotational shift amount (Δθ) fall within allowable ranges, preferably become 0. This adjusts the position and rotation angle of the substrate S. This operation will be called pre-alignment.

In the second mode, the adjuster 20 executes the above pre-alignment and also executes offset correction to adjust the position and rotation angle of the substrate S by driving the substrate S based on offset values provided from the controller 16. The offset correction is the processing of adjusting the position and rotation angle of the substrate S based on offset values (Δxo, Δyo, Δθo) set in advance with respect to one of the processors 11, 12, 13, and 14 to which the substrate S is conveyed. Assume that (x, y) represents the design position of the substrate S when the processor receives the substrate S, θ (for example, 0) represents the design rotation angle of the substrate S when the processor receives the substrate S, and (Δxo, Δyp, Δθo) represents offset values set in advance with respect to the processor. In this case, the adjuster 20 can adjust the position and rotation angle of the substrate S in accordance with the offset values (Δxo, Δyo, Δθo). Thereafter, the conveyance mechanism 15 conveys the substrate S to the processor 11 in accordance with (x, y, θ). Offset values can be set in advance in consideration of, for example, a conveyance error in the substrate S which is caused by the conveyance mechanism 15 and errors and the like intrinsic to each processor. The errors intrinsic to each processor can include, for example, an error relative to a reference position on an alignment scope mounted in the processor and an error relative to a reference position on a mold (original).

The adjuster 20 may be provided in the loading unit 152 or another place. When the adjuster 20 is provided in the loading unit 152, for example, the substrate S processed in a previous step can be directly supplied to the adjuster 20. The apparatus 100 can further include the standby port 154. The standby port 154 can be used to receive and transfer a vessel containing the substrate S.

The adjuster 20 adjusts at least the position (preferably both the position and rotation angle) of the position and rotation angle of the substrate to be processed (substrate S) supplied to the loading unit 152 or the standby port 154. The conveyance mechanism 15 then conveys the substrate to be processed to the first processor, which is one of the processors 11, 12, 13, and 14. The first processor then processes the substrate. Thereafter, the conveyance mechanism 15 conveys the substrate to be processed from the first processor to the unloading unit 153. The unloading unit 153 then unloads the substrate to the outside of the apparatus 100. In this case, if there is a trouble in the first processor to which the substrate to be processed should be conveyed, the controller 16 controls the conveyance mechanism 15 to convey the substrate to be processed to the second processor, of the plurality of processors 11, 12, 13, and 14, which is different from the first processor. In this case, the controller 16 controls the conveyance mechanism 15 to convey the substrate to be processed to the second processor without causing the adjuster 20 to adjust the position (and rotation angle) of the substrate to be processed.

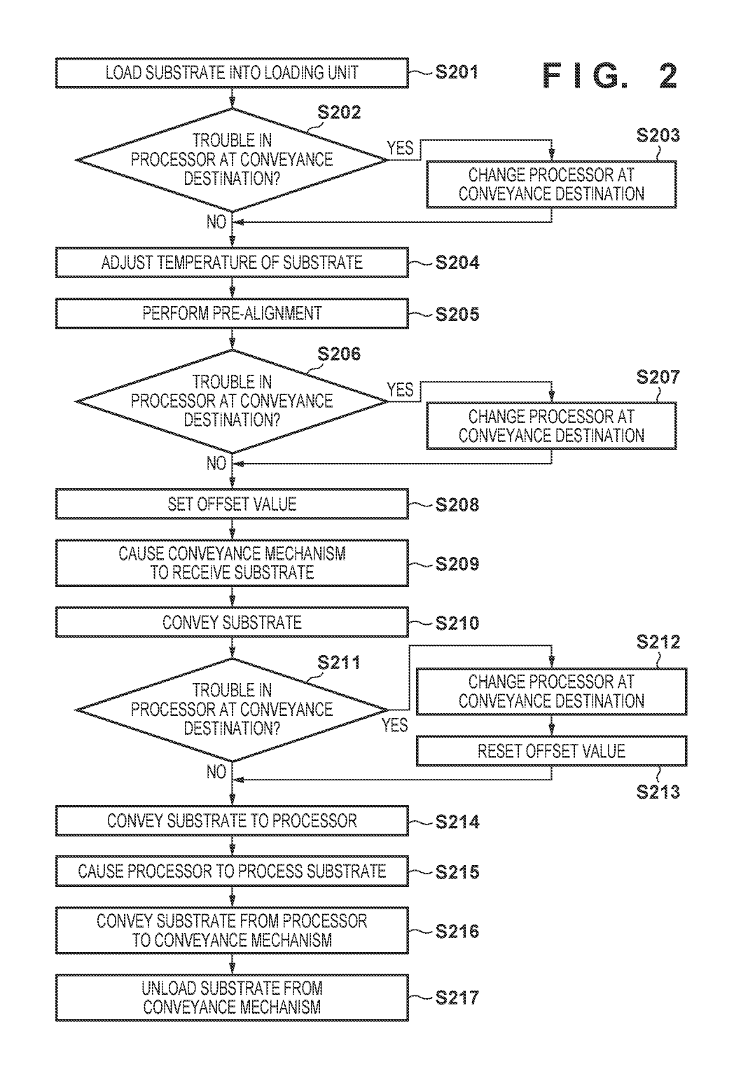

The operation of the apparatus 100 in the first mode will be described below with reference to FIG. 2. In step S201, the substrate S is loaded as a substrate to be processed into the loading unit 152 or the standby port 154. In step S202, the controller 16 determines whether a trouble (error) has occurred in one of the plurality of processors 11, 12, 13, and 14 which is planned to process the substrate to be processed. Upon determining in step S202 that a trouble has occurred in the processor planned to process the substrate to be processed, the controller 16 changes the processor planned to process the substrate to be processed to another processor of the plurality of processors 11, 12, 13, and 14 in step S203.

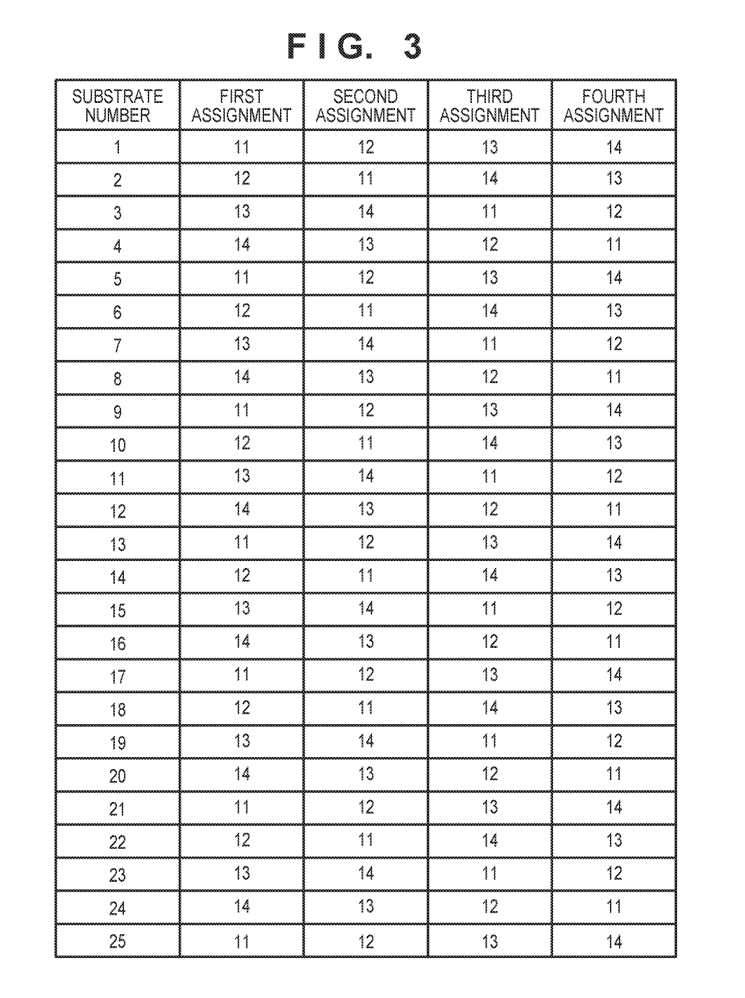

FIG. 3 schematically shows a table for selecting a processor which processes a substrate to be processed. “Substrate number” is a number for identifying a substrate to be processed. A substrate to be processed assigned with substrate number=1 is planned to be processed by the processor 11 corresponding to the first assignment. If, however, there is a trouble in the processor 11, the substrate to be processed assigned with substrate number=1 is processed by the processor 12 corresponding to the second assignment. A substrate to be processed assigned with substrate number=2 is planned to be processed by the processor 12 corresponding to the first assignment. If, however, there is a trouble in the processor 12, the substrate to be processed assigned with substrate number=2 is processed by the processor 11 corresponding to the second assignment. If there is a trouble in a processor planned to process a substrate to be processed, the processing target is processed by another processor, thereby making it possible to prevent a reduction in the operating rate of the apparatus 100 and improve the throughput. In the case shown in FIG. 3, the first to fourth assignments are set. However, in an apparatus for processing a substrate with a low frequency of occurrence of errors, the number of assignments may be reduced. In contrast, in an apparatus for processing a substrate including a large number of processors and having a high frequency of occurrence of errors, the number of assignments may be increased.

In step S204, the controller 16 adjusts the temperature of the substrate to be processed in the loading unit 152. This temperature adjustment may be the processing of waiting for the elapse of a predetermined time or the processing of forcibly adjusting the temperature of the substrate to be processed. In step S205, the controller 16 causes the adjuster 20 to adjust at least the position (preferably both the position and rotation angle) of the position and rotation angle of the substrate to be processed. That is, in step S205, the controller 16 causes the adjuster 20 to execute pre-alignment of the substrate to be processed.

In pre-alignment, the measurement unit of the adjuster 20 measures the positional shift amount (Δx, Δy) relative to the target position (x, y), and the rotational shift amount (Δθ) relative to the target rotation angle (θ). The driver of the adjuster 20 then drives the substrate to be processed so as to make the positional shift amount (Δx, Δy) and the rotational shift amount (Δθ) fall within the allowable ranges. This adjusts the position and rotation angle of the substrate to be processed to the target position (x, y) and the target rotation angle (θ).

In step S206, the controller 16 determines whether a trouble (error) has occurred in the first processor which is one of the plurality of processors 11, 12, 13, and 14 which is currently assigned to process the substrate to be processed. Upon determining in step S206 that a trouble has occurred in the first processor, the controller 16 changes, in step S207, the processor which processes the substrate to be processed to the second processor, of the plurality of processors 11, 12, 13, and 14, which is different from the first processor. This change can be made in accordance with the table exemplarily shown in FIG. 3. In this case, the processor assigned to process the substrate to be processed at the time of the completion of the pre-alignment in step S205 is called the first processor, and the processor which has been changed from the first processor is called the second processor.

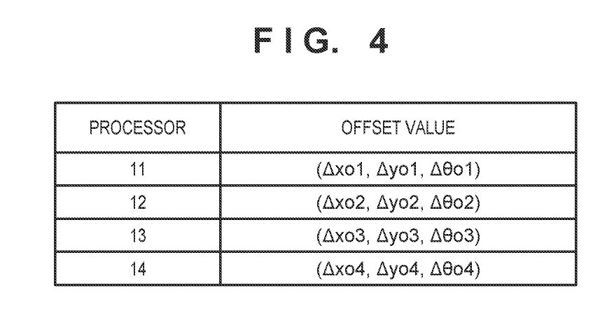

In step S208, the controller 16 sets the offset values (Δxo, Δyo, Δθo) set in advance with respect to the processor at the substrate conveyance destination as control parameters. The processor at the substrate conveyance destination is the first processor when step S207 has not been executed. When step S207 has been executed, this processor is the second processor. The offset values (Δxo, Δyo, Δθo) set in step S208 are referred to as control parameters when the conveyance mechanism 15 conveys the substrate to be processed later in step S214. FIG. 4 schematically shows offset values respectively set in advance with respect to the processors 11, 12, 13, and 14. For example, (Δxol, Δyol, Δθl) are set in advance as offset values with respect to the processor 11. The offset values may be updated based on measurement results in the processors 11, 12, 13, and 14.

Subsequently, in step S209, the controller 16 controls the conveyance mechanism 15 to receive the substrate to be processed from the adjuster 20. In step S210, the controller 16 controls the conveyance mechanism 15 to convey the substrate to be processed from the loading unit 152 to the processor at the substrate conveyance destination. The processor at the substrate conveyance destination is the first processor when step S207 has not been executed, and is the second processor when step S207 has been executed.

In step S211, the controller 16 determines whether a trouble (error) has occurred in one of the plurality of processors 11, 12, 13, and 14 which is located at the substrate conveyance destination. Upon determining in step S211 that a trouble has occurred in the processor at the substrate conveyance destination, the controller 16 changes the processor at the substrate conveyance destination in step S212. That is, in step S212, the controller 16 changes the processor which processes the substrate to be processed to another processor of the plurality of processors 11, 12, 13, and 14. This change can be made in accordance with the table exemplarily shown in FIG. 3. Step S211 may be executed before the execution of step S210. In step S213, the controller 16 resets the offset values (Δxo, Δyo, Δθo) set in advance with respect to the processor at the substrate conveyance destination. That is, the offset values set in step S208 are changed in step S213.

In step S214, the controller 16 controls at least one of the conveyance mechanism 15 and the processor at the substrate conveyance destination so as to place the substrate to be processed at a target position in the processor at the substrate conveyance destination. This control will be called position-related offset control. Position-related offset control is performed in accordance with an offset value (Δxo, Δyo) set in step S208 or S213. When a target rotation angle is to be also regarded as a control target, the controller 16 controls at least one of the conveyance mechanism 15 and the processor at the conveyance destination so as to arrange the substrate to be processed at the target position at the target rotation angle. This control will be called position/rotation-angle-related offset control. Position/rotation-angle-related offset control is performed in accordance with the offset values (Δxo, Δyo, Δθo) set in step S208 or S213.

When at least one of steps S207 and S213 is executed, the controller 16 controls at least one of the conveyance mechanism 15 and the processor at the substrate conveyance destination so as to arrange the substrate to be processed at the target position in the second processor at the target rotation angle. If the processor has not changed after the pre-alignment for the substrate to be processed (step S205), the controller 16 controls at least one of the conveyance mechanism 15 and the processor at the conveyance destination so as to arrange the substrate to be processed at the target position in the first processor at the target rotation angle.

An offset control method will be described below. Position-related offset control can be performed by controlling the position of a substrate to be processed (that is, the conveyance target position of the conveyance mechanism 15) when the conveyance mechanism 15 transfers the substrate to be processed to the substrate holder of the processor at the substrate conveyance destination. That is, when the design conveyance target position of a substrate to be processed is represented by (x, y), the substrate to be processed may be conveyed by the conveyance mechanism 15, with (x+Δxo, y+Δyo) obtained by correcting (x, y) using the offset value (Δxo, Δyo) being regarded as a conveyance target position.

Alternatively, position-related offset control can be performed by controlling the position of a substrate to be processed when the substrate holder of the processor at the substrate conveyance destination receives the substrate to be processed. That is, the substrate holder preferably receives the substrate to be processed in a driven state while the position of the substrate holder is driven by (−Δxo, −Δyo) in accordance with the offset value (Δxo, Δyo).

Rotation-related offset control is additionally performed with respect to the above position-related offset control. Rotation-related offset control can be performed by controlling the rotation of the substrate holder of the processor at the substrate conveyance destination in accordance with the offset value (Δθ) so as to set the rotation angle of the substrate to be processed to the target rotation angle in the processor. In this case, it is possible to use a method of rotating the substrate holder of a processor at a conveyance destination by −Δθ before the substrate holder receives the substrate to be processed and then returning the rotation of the substrate holder to the initial rotation after the substrate holder receives the substrate to be processed. Alternatively, the substrate holder of a processor at the conveyance destination may be rotated through Δθ after the substrate holder receives the substrate to be processed.

As described above, when the conveyance destination of the substrate to be processed is changed from the first processor to the second processor after the pre-alignment by the adjuster 20 in step S205, the substrate to be processed is conveyed to the second processor without causing the adjuster 20 to execute pre-alignment. This cuts the time required for repetition of pre-alignment and conveyance of the substrate to be processed because of the pre-alignment, thereby improving the throughput.

In step S215, the controller 16 causes the processor at the substrate conveyance destination to process the substrate to be processed. More specifically, this processing can include measuring a shot array on the substrate to be processed, supplying an imprint material onto a shot region, aligning the shot region with a hold (original), and curing the imprint material.

In step S216, the controller 16 controls the conveyance mechanism 15 to convey the substrate to be processed having undergone the processing from the processor to the unloading unit 153. In step S217, the substrate to be processed is unloaded from the unloading unit 153 to the outside of the apparatus 100.

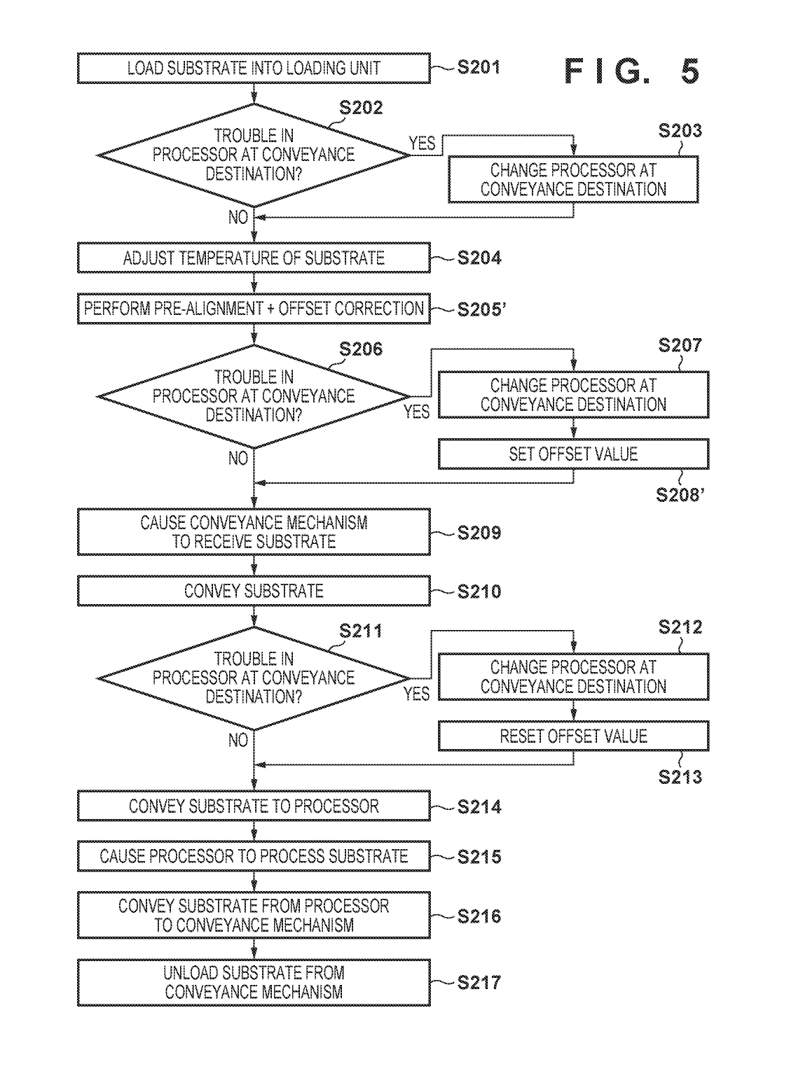

The operation of the apparatus 100 in the second mode will be described below with reference to FIG. 5. The second mode is the mode in which step S205 in the first mode is changed to step S205′, and step S208 in the first mode is changed to step S208′. To avoid a redundant description, only steps S205′ and S208′ will be described.

In step S205′, the controller 16 causes the adjuster 20 to execute pre-alignment and offset correction. The controller 16 causes the adjuster 20 to execute pre-alignment and offset correction concerning at least the position (preferably both the position and rotation angle) of the position and rotation angle of the substrate to be processed.

In pre-alignment, the measurement unit of the adjuster 20 measures the positional shift amount (Δx, Δy) relative to the target position (x, y), and the rotational shift amount (Δθ) relative the target rotation angle (θ). The driver of the adjuster 20 then drives the substrate to be processed so as to make the positional shift amount (Δx, Δy) and the rotational shift amount (Δθ) fall within the allowable ranges. This adjusts the position and rotation angle of the substrate to be processed to the target position (x, y) and the target rotation angle (θ).

In offset correction, the driver of the adjuster 20 adjusts the position and rotation angle of the substrate to be processed in accordance with a command from the controller 16 so as to comply with the offset values (Δxo, Δyo, Δθo) with respect to the first processor planned to process the substrate to be processed. In this case, the driver of the adjuster 20 may drive the substrate to be processed based on the total values of (Δx, Δy, Δθ) in pre-alignment and (Δxo, Δyo, Δθo) in offset correction.

In the first mode, step S208 is executed in either of the following cases: when no trouble is detected in step S206, and when a trouble is detected in step S206, and the processor at the substrate conveyance destination is changed in step S207. In contrast to this, in the second mode, step S208′ replacing step S208 is executed only when the processor at the substrate conveyance destination is changed in step S207. The processing contents in step S208′ themselves are the same as those in step S208. In step S208′, the controller 16 sets the offset values (Δxo, Δyo, Δθo) set in advance with respect to the processor at the substrate conveyance destination as control parameters for offset control.

The second mode is advantageous when, for example, an offset value (Δθo) concerning rotation set in advance with respect to the first processor and an offset value (Δθo) concerning rotation set in advance with respect to the second processor are large and close to each other. If, for example, the offset values (Δθo) concerning rotation set in advance with respect to the first and second processors are larger than the allowable rotation amount of the substrate holder, it is advantageous to cause the adjuster 20 to rotate the substrate in accordance with the offset values (Δθo). This is because, in order to cause the substrate holder to rotate the substrate beyond the allowable rotation amount, it is necessary to re-mount the substrate on the substrate holder a plurality of times. In this case, to re-mount the substrate a plurality of times is to, for example, repeat the operation of rotating the substrate holder in the first direction while the substrate is held by a lift pin and then rotating the substrate holder in the second direction opposite to the first direction while the substrate is mounted on the substrate holder.

A method of manufacturing a device (a semiconductor integrated circuit device, liquid crystal display device, or the like) as an article includes a process of forming a pattern on a substrate (a wafer, glass plate, film-like substrate, or the like) by using the above imprint apparatus. The manufacturing method further includes a process of processing (for example, etching) the substrate on which the pattern is formed. Note that when manufacturing other articles such as patterned media (recording media) and optical devices, the manufacturing method can include, in place of etching, another process of processing a substrate on which a pattern is formed. The method of manufacturing an article according to the embodiment is more advantageous than the related art in terms of at least one of the performance and quality of an article, productivity, and a production cost.

Although the preferred embodiment of the present invention has been described above, the present invention is not limited to the embodiment, and various modifications and changes can be made within the spirit and scope of the invention.

### Other Embodiments

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2015-140785, filed Jul. 14, 2015, which is hereby incorporated by reference herein in its entirety.

What is claimed is:

1. An apparatus for processing a substrate, comprising a plurality of processors configured to process a substrate, an adjuster configured to adjust a position of the substrate, a conveyance mechanism configured to convey the substrate, and a controller,
wherein the controller controls the adjuster to adjust a position of a substrate to be processed which is to be conveyed to a first processor of the plurality of processors,
the controller controls the conveyance mechanism to convey the substrate to be processed to a second processor of the plurality of processors without causing the adjuster to readjust the position of the substrate to be processed when there is a trouble in the first processor while the position of the substrate to be processed has been adjusted by the adjuster, and
the controller controls at least one of the conveyance mechanism and the second processor such that the substrate to be processed is arranged at a target position in the second processor.

2. The apparatus according to claim 1, wherein in a case where the controller causes the conveyance mechanism to convey the substrate to be processed to the second processor, the controller controls the position of the substrate to be processed, when the conveyance mechanism transfers the substrate to be processed to a substrate holder of the second processor, such that the substrate to be processed is arranged at the target position in the second processor.

3. The apparatus according to claim 2, wherein the adjuster adjusts a rotation angle of a substrate in addition to a position of the substrate, and
the controller controls the adjuster to adjust the position and the rotation angle of the substrate to be processed to be conveyed to the first processor, and
the controller controls rotation of the substrate holder of the second processor to set the rotation angle of the substrate to be processed to a target rotation angle in the second processor in a case where the controller causes the conveyance mechanism to convey the substrate to be processed to the second processor.

4. The apparatus according to claim 3, wherein in a case where the controller causes the conveyance mechanism to convey the substrate to be processed to the second processor, the controller rotates the substrate holder to set the rotation angle of the substrate to be processed to the target rotation angle in the second processor before the substrate holder of the second processor receives the substrate to be processed, and returns the rotation of the substrate holder to initial rotation after the substrate holder receives the substrate to be processed.

5. The apparatus according to claim 3, wherein in a case where the controller causes the conveyance mechanism to convey the substrate to be processed to the second processor, the controller rotates the substrate holder to set the rotation angle of the substrate to be processed to the target rotation angle in the second processor after the substrate holder of the second processor receives the substrate to be processed.

6. The apparatus according to claim 1, wherein in a case where the controller causes the conveyance mechanism to convey the substrate to be processed to the second processor, the controller controls the position of the substrate holder of the second processor, when the substrate holder receives the substrate to be processed, so as to arrange the substrate to be processed at the target position in the second processor.

7. The apparatus according to claim 6, wherein the adjuster adjusts a rotation angle of a substrate in addition to a position of the substrate, and
the controller controls the adjuster to adjust the position and the rotation angle of the substrate to be processed which is to be conveyed to the first processor, and
the controller controls rotation of the substrate holder of the second processor to set the rotation angle of the substrate to be processed to a target rotation angle in the second processor in a case where the controller causes the conveyance mechanism to convey the substrate to be processed to the second processor.

8. The apparatus according to claim 7, wherein in a case where the controller causes the conveyance mechanism to convey the substrate to be processed to the second processor, the controller rotates the substrate holder to set the rotation angle of the substrate to be processed to the target rotation angle in the second processor before the substrate holder of the second processor receives the substrate to be processed, and returns the rotation of the substrate holder to initial rotation after the substrate holder receives the substrate to be processed.

9. The apparatus according to claim 7, wherein in a case where the controller causes the conveyance mechanism to convey the substrate to be processed to the second processor, the controller rotates the substrate holder to set the rotation angle of the substrate to be processed to the target rotation angle in the second processor after the substrate holder of the second processor receives the substrate to be processed.

10. The apparatus according to claim 1, wherein the controller controls the adjuster to adjust the position of the substrate to be processed in accordance with an offset value for the first processor in a case where the controller causes the adjuster to adjust the position of the substrate to be processed.

11. The apparatus according to claim 1, wherein the controller controls the adjuster to adjust the position of the substrate to be processed in accordance with an offset value for the first processor in a case where the controller causes the adjuster to adjust the position of the substrate to be processed.

12. The apparatus according to claim 3, wherein the control unit controls the adjuster to adjust the position of the substrate to be processed in accordance with an offset value for the first processor in a case where the controller causes the adjuster to adjust the position and the rotation angle of the substrate to be processed.

13. The apparatus according to claim 7, wherein the controller controls the adjuster to adjust the position of the substrate to be processed in accordance with an offset value for the first processor in a case where the controller causes the adjuster to adjust the position and the rotation angle of the substrate to be processed.

14. The apparatus according to claim 1, wherein each of the plurality of processors comprises a lithography apparatus.

15. A method of manufacturing an article, comprising:
forming a pattern on a substrate; and
processing the substrate on which the pattern is formed,
wherein in the processing the substrate, an apparatus for processing a substrate is used, the apparatus comprising a plurality of processors configured to process a substrate, an adjuster configured to adjust a position of the substrate, a conveyance mechanism configured to convey the substrate, and a controller,
wherein the controller controls the adjuster to adjust a position of a substrate to be processed which is to be conveyed to a first processor of the plurality of processors,
the controller controls the conveyance mechanism to convey the substrate to be processed to a second processor of the plurality of processors without causing the adjuster to readjust the position of the substrate to be processed when there is a trouble in the first processor while the position of the substrate to be processed has been adjusted by the adjuster, and
the controller controls at least one of the conveyance mechanism and the second processor such that the substrate to be processed is arranged at a target position in the second processor.
